(19) United States
(12) Patent Application Publication
(10) Pub. No.: US 2008/0032039 A1
(43) Pub. Date: Feb. 7, 2008

(54) Method of manufacturing organic electroluminescence device

(75) Inventor: Koji Murata, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 11/880,675

(22) Filed: Jul. 23, 2007

(30) Foreign Application Priority Data
Aug. 7, 2006 (JP) 2006-214324

(51) Int. Cl. B05D 5/12

(52) U.S. Cl. 427/66

(57) ABSTRACT

A method of manufacturing an organic EL device without a defect or an unevenness is provided by forming a film uniformly without ink repellent phenomenon in a method where an organic electroluminescence medium layer is formed by transferring an ink inside a pixel sectioned by a partition wall by relief printing. One embodiment of the present invention is a method of manufacturing an organic electroluminescence device, including making a partition wall pattern hydrophilic; and forming an organic electroluminescence medium layer by transferring an ink in a area sectioned by the partition wall by relief printing.

### CROSS REFERENCE

This application claims priority to Japanese application number 2006-214324, filed on Aug. 7, 2006, which is incorporated by reference.

### BACKGROUND OF THE INVENTION

1. Field of the Invention

The present invention relates to a method of manufacturing an organic electroluminescence (light emitting) device. More particularly, the present invention relates to a method of manufacturing an organic electroluminescence device which emits light uniformly, wherein a hole transport layer of an organic electroluminescence device is formed by a relief printing method.

2. Description of the Related Art

An organic electroluminescence device has an hole transport layer including a hole transport material and an organic light emitting layer including organic light emitting material between two opposed electrodes. It emits light by electric current to the organic light emitting layer. Herein, a member comprising the two layers is called as the organic light emitting (electroluminescence) medium layer. Film thickness of the light emitting medium layer is important, and it is necessary to make the film of around 100 nm to emit light efficiently. Even more particularly, it is necessary to form the light emitting medium layer thin to make a display unit.

In an organic light emitting material and a hole transport material forming an organic light emitting medium layer, there are low molecular materials and high polymeric materials. Generally, with low molecular materials, thin film can be formed by vacuum evaporation. A mask with minute pattern is used, and patterning is performed. In this approach, upsizing of the substrate results in diminishing of pattern accuracy. In addition, it is layered in vacuum, therefore, the throughput is bad.

Thus the following method is tried recently. A polymer organic light emitting material is dissolved in a solvent, and an ink is made. This ink is used, and thin film is formed by a wet coating method.

A layer structure of an organic light emitting medium layer when an organic light emitting medium layer including an organic light emitting layer is formed by wet coating using coating solution of high polymer materials is described below. The two-layer construction which a hole transport layer and an organic light emitting layer are laminated on an anode side is generally used. As for the organic light emitting layer, it is necessary for the organic light emitting inks including organic light emitting materials of red (R) green (G) and blue (B) in a solvent to be applied independently in order to form a color panel.

On the other hand, a hole transport layer is generally applied on a whole area contributing to imaging of an organic electroluminescent display panel without patterning the hole transport layer. A hole transport layer is formed by coating methods such as a spin coat method and a die coat method. Generally a hole transport layer is a thin film of which thickness is equal to or less than 100 nm. Therefore, an electric current is easy to spread in a depthwise direction of a hole transport layer than a transverse direction of a hole transport layer. Therefore, it is said that leakage current to the outside of a picture element is very little if patterning of electrode is performed.

In the above-mentioned application method, patterning every pixel is not necessary, however a film is formed on a place where an adhesive for sealing is applied and a place where a driver chip is equipped, thereby it is necessary to wipe and remove an unnecessary part of a hole transport layer after a hole transport layer is applied.

Therefore, it is very important to form a pattern of not only an organic light emitting layer but also a hole transport layer only on a pixel electrode in order to shorten the processes and to reduce the cost.

However, a hole transport material forming a hole transport layer consists of a polymer material such as (3,4-polyethylen dihydroxy thiophen) (PEDOT):(PSS)(polystylene sulfonate). A hole transport ink is made by dissolving this hole transport material in a solvent. In consideration of solubility of a polymer material and necessity of thin film formation, it is necessary for the concentration of a hole transport ink to be low. For example, the concentration is around 2%.

Partition walls are necessary to prevent ink from spreading when the low-viscosity hole transport ink of which concentration is around 2% is printed in the shape of pattern. A high insulator layer should be formed between pixel electrodes, and it should be used as a partition wall. Hole transport ink is applied on pixel electrodes sectioned by an partition wall. In this case, a printing process such as an ink jet method or relief printing can be used.

In an ink jet method an ink is discharged multiple times on a substrate from ink jet nozzles. A discharge jet is separated from a substrate. Therefore, ink spreads by only own weight between partition walls on a substrate. Thus, it is difficult to apply ink to a whole area surrounded by a partition wall by an ink jet method. Especially, print omissions easily occur in edges of pixel electrodes.

The method how print omission does not occur in an ink jet method is designed. However it is necessary to apply ink sufficiently to an aperture to prevent print omission. In this case, it is necessary to prevent ink from overflowing a partition wall. Therefore, it is necessary to do water-repellent processing for a partition wall. Then the number of the processes increases. Even more particularly, as for the ink applied between water repellent partition walls, it is in heaping full condition. Therefore, film thickness uniformity in a picture element becomes bad. Therefore, there is a problem in an aspect of homogeneity and stability of a display panel.

As described above, it is necessary to use an effective method of forming a pattern of each layer in order to manufacture a full-color panel having a good display quality. On the other hand, it is necessary for a method of forming a thin film to be an inexpensive and simple method in order to use the method for the industry.

On the other hand, relief parts of a relief printing plate push a substrate in relief printing. In addition, a relief parts is put in a space surrounded by partition walls. Therefore, the ink is expanded in a picture element surrounded with partition walls. Thus, print omissions in edges of pixel electrodes are hard to occur. In addition, relief printing method is simple and easy, and throughput is good as compared to ink jet method. Thus, when a hole transport layer is formed using hole transport ink, relief printing is preferred.

Relief printing method is defined as a method using a relief printing plate in the broad sense. Relief printing method of the present invention is a printing method which uses a relief printing plate comprising a rubber printing plate or a resin printing plate. In addition, a printing method which uses a rubber relief printing plate is referred to as flexography in the printing industry. In addition, a printing method which uses a plastic plate is referred to as the plastic plate printing method. However, printing methods of both are referred to as relief printing method in the present invention.

As for the rubber plate and the resin plate used in relief printing, photosensitive rubber plate and resin plate are employed mainly now. On the other hand, materials of relief printing plate are multiplied. Difference of photosensitive rubber plate and photosensitive resin plate becomes uncertain. Therefore, in present specification, both are referred to as light-sensitive resin relief printing plate.

In forming an organic electroluminescence medium layer between partition walls by relief printing using an ink, an ink liquid also adheres to a pixel other than a predetermined pixel, thereby ink materials are mixed with each other and color purity, light emitting efficiency and life time become bad. In order to solve such problems, a partition wall having a critical surface tension lower than a surface tension of an ink is proposed. (JP-A-2003-243163)

In order to obtain an organic electroluminescence (EL) display having a good property by forming a hole transport layer without a defect and a unevenness by a relief printing, actually, it is necessary to make such a partition wall having a sufficient wettability that an ink transferred to a substrate is hardly repelled by a partition wall or the like, since an amount of an ink transferred by relief printing is a little.

A partition wall pattern is usually formed by a general photolithography process including a step of applying a photoresist on a substrate and a step of exposure and development. Generally a photoresist include a little of a surface-active agent in order to improve a coating performance and a film formation performance and in order to prevent unevenness. These surface-active agents are generally hydrophobic. Especially, the surface-active agents bleed out too much on a substrate, thereby an ink repellent phenomenon or a void in a pixel very easily occurs when water type hole transport ink is applied to a substrate. In addition, in a hardening process, hydrophilic functional group frequently become a bridge formation point, thereby there is a problem that hydrophilic character of a resin after hardening is lowered. In order to be able to form a hole transport layer between such a partition wall, it is necessary to use such techniques that a solvent or other surface-active agent is added to a hole transport ink to reduce a surface tension of a hole transport ink. Even if a solvent used for reducing a surface tension of an ink is a water type, an ink composition becomes unstable and an ink may separate out, thereby there is a problem that unevenness easily occurs since it is difficult to dry an ink uniformly. In addition, since a surface-active agent generally has low volatile property, a surface-active agent remains in a hole transport layer after drying, thereby it is pointed out that a surface-active agent gives harmful influence on a light emitting performance and a life time of an organic EL device. The number of the kinds of the usable inks which solve the above-mentioned problem is very limited, thereby formula for an ink is difficult.

### SUMMARY OF THE INVENTION

The objective of the present invention is to provide a method of manufacturing an organic EL device without a defect or an unevenness, by forming a film uniformly without ink repellent phenomenon in a method where an organic electroluminescence medium layer is formed by transferring an ink, inside a pixel sectioned by a partition wall, by relief printing. One embodiment of the present invention is a method of manufacturing an organic electroluminescence device, comprising: making a partition wall pattern hydrophilic; and forming an organic electroluminescence medium layer by transferring an ink in a area sectioned by the partition wall by relief printing.

### BRIEF DESCRIPTION OF DRAWINGS

FIG. 1 is a schematic diagram of a structure of an organic EL device in an organic EL panel according to the present invention.

FIG. 2 is a schematic diagram of a relief printing apparatus used in the present invention.

In these drawings, 1 is a transparent substrate; 2 is a pixel electrode; 3 is a partition wall; 4 is a hole transport layer; 5 is an organic light emitting layer; 6 is a cathode layer; 7 is a glass cap; 8 is an adhesive; 10 is an ink tank; 12 is an ink chamber; 14 is an anilox roll; 14a is a ink layer; 16 is a printing plate; 18 is a plate cylinder; 20 is a flat base: and 24 is a substrate.

### DESCRIPTION OF THE PREFERRED EMBODIMENTS

According to the study by the inventor, it was found that hydrophilic property of a surface became good by light irradiation after applying a photosensitive resin component to form a partition wall on a substrate, exposing a pattern of the resin and developing the resin, thereby a partition wall having an ink resistant property which was not solved by a hole transport ink could be obtained.

As an embodiment of a method of manufacturing an organic electroluminescence device of the present invention, an example of manufacturing a passive matrix type organic electroluminescence panel is described below. However, the present invention is not limited to the example.

Herein, examples of other embodiments include an active matrix type and a segment type.

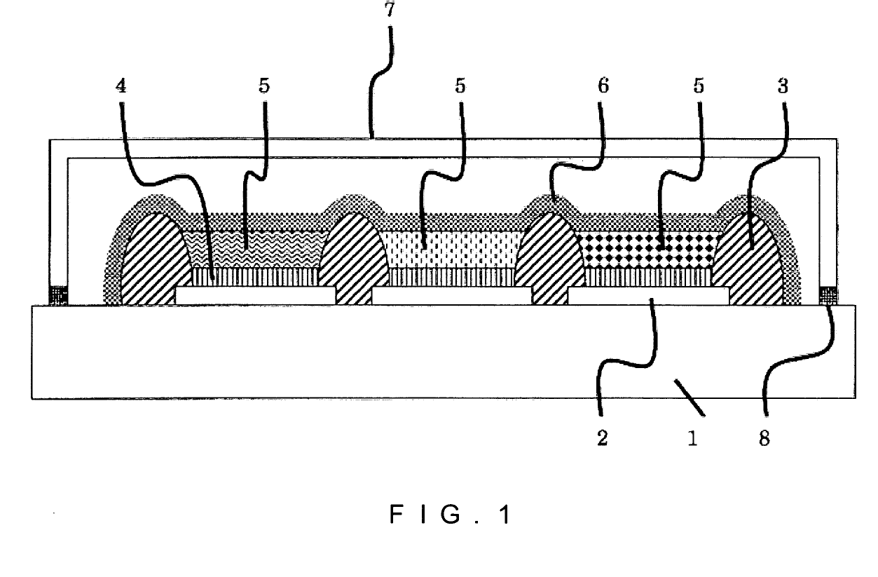

FIG. 1 is a cross-sectional schematic diagram of an organic electroluminescence panel in the present invention.

An organic electroluminescence device in an organic electroluminescence panel is formed on transparent substrate 1. For a transparent substrate 1, a glass substrate and a plastic film or sheet can be used. If a plastic film is used, a polymer type electroluminescent device can be manufactured by take-up. In other words an inexpensive display panel can be manufactured. In addition, for the plastic, polyethylene terephthalate, polypropylene, cyclo-olefin polymers, polyamide, polyethersulfone, polymethyl methacrylate and polycarbonate can be used. In addition, steam or oxygen barrier layer comprising metallic oxide such as silicon oxide, oxynitrides such as silicon nitrides and polyvinylidene chloride, polyvinyl chloride, saponified ethylene-vinyl acetate copolymer can be formed on these films if necessary.

Pattern-formed pixel electrodes 2 are formed on a transparent substrate as anodes. For materials of pixel electrodes 2, transparent electrode materials such as ITO (indium tin complex oxide), IZO (indium zinc complex oxide), tin oxide, zinc oxide, indium oxide and aluminium oxide complex oxide can be used.

In addition, electrical resistance of ITO is low. ITO has solvent resistance. ITO is transparent. Therefore, ITO is preferable.

ITO is formed on a transparent substrate by sputter method, ion plating method, vapor deposition method or the like. Patterning of ITO is performed by photolithography method. ITO becomes line-shaped pixel electrodes 2 in this way.

And, partition wall 3 is formed between adjacent pixel electrodes by photolithography method using a photosensitive material. In detail, this process comprises a step of applying a photosensitive resin composition on a substrate, a step of forming a partition wall pattern by exposure and development and a step of making a partition wall hydrophilic by light irradiation.

In addition, hydrophilic processing is not especially limited and includes light irradiation, plasma exposure, corona discharge or the like.

Examples of plasma exposure include atmospheric-pressure plasma, vacuum plasma, oxygen plasma or the like.

A photosensitive resin can be used as formation material of partition wall. Both a positive type resist and a negative type resist can be used. Commercial material can be used. Formation material of partition wall has to have enough insulating properties. When partition wall does not have enough insulating properties, adjacent electrodes short-circuit through partition wall. Therefore, display defects occur. By way of example only, material such as polyimide system, an acryl resin system, a novolak resin system or a fluorene system can be used. However, usable material is not limited to these materials. In addition, light shielding materials may be included in the above described materials for partition wall formation for the purpose of improving display quality of an organic electroluminescent element.

A light-sensitive resin for forming partition wall 3 is applied by a well-known application machines such as a spin coater, a bar coating machine, a roll coater, a die coating machine and an engraved-roll coater. In a next step of forming a partition wall pattern by exposing the light-sensitive resin in patterns and developing, a pattern of a part of a partition wall can be formed by conventional well-known methods of exposing and developing.

In a step of making a partition wall pattern hydrophilic by light irradiation, ultra-violet ray or the like is irradiated from above a substrate to make a partition wall part and an anode part hydrophilic. Ultra-violet ray used for ultra-violet cleaning is preferable as an irradiation light, and ultra-violet irradiation treatment by an extra high pressure mercury lamp, an high-pressure mercury lamp, a metal halide lamp or the like is preferable. An irradiation light may include a photosensitive wavelength of a photosensitive resin to form a partition wall or may not include a photosensitive wavelength of a photosensitive resin to form a partition wall. In a case where an irradiation light includes a photosensitive wavelength of a photosensitive resin, a resist is sensitive. In this case, if a resist is positive type, a resist becomes soluble in a developer. For example, in a case where an alkaline development type photosensitive resin is used, the alkaline development type photosensitive resin can not developed if a hole transport ink is neutral or acid, thereby ink resistant property does not become poor. In the case where a negative resist is used, curing of a resin is advanced, thereby there is not problem of ink resistant property.

In addition, in a case of a water type hole transport ink, a process to reduce a surface tension by adding an alcohol or a solvent can be conducted. In this case, if the light irradiation process is only conducted, ink resistant property of a partition wall may be poor. There is a case where it is necessary to improve an ink resistant property by a combination of “a partition wall material and a hole transport ink”. In such a case, before light irradiation, a partition wall can be temporarily hardened by heat process at a temperature of 160° C. or less. In some embodiments, the lower value of the heat process temperature should not be less than 80° C. Examples of heating process include heating by a hot air circulating oven, a hot plate, infra-red ray or the like and the examples is not limited to these apparatus. On the other hand, in a case where heating at 160° C. or higher are conducted, surface-active agent bleeds out too much, thereby a surface of a partition wall have much ink-repellent property. In addition, in a case where hardening of a resin is advanced, development functionality is consumed by a hardening reaction, therefore hydrophilic property of a material itself is lowered. This phenomenon is not preferable.

It is desirable that thickness of partition wall 3 in the present invention should be 0.5 μm-5.0 μm. By providing partition wall 3 between adjacent pixel electrodes 3, a hole transport ink printed on each of the pixel electrodes can be prevented from flowing and the short circuit at an end of a transparent conductive layer can be prevented from occurring. Since the short circuit is not always prevented if a partition wall is too low, the height of a partition wall is important.

In addition, for example, in a case of a passive matrix type organic electroluminescence display panel, when partition wall 3 is formed between pixel electrodes, partition wall 3 is formed so as to be perpendicular to a cathode layer. In a case where a cathode layer is formed across over a partition wall, if partition wall is too high, a cathode layer may be cut and display defect may be occurred. When height of partition wall 3 is higher than 5.0 μm, the cutting of the cathode is easily occurred.

After forming partition wall 3, hole transport layer 4 is formed. In the present invention, it is desirable that a water type hole transport ink having pH of 3 or less should be used to form hole transport layer 4. In some embodiments, pH should not be les than 1. This is because, if solvent type is used, such problems that hole transport ink separates out occurs easily. In addition, the above-mentioned dispersion type hole transport ink is often acid. In the invention, it is desirable that the acid ink should be used without making the ink neutral. This is because it is possible that the stability of the ink becomes worse or the hole transport property becomes poor by making the ink neutral. In addition, making the ink neutral by an inorganic alkali or the like should be avoided because ion component is mixed and the life time is shortened.

As the above-mentioned hole transport ink, poly(3,4-ethylenedioxy thiophene) (PEDOT):(PSS) is especially preferable in the light of conductivity and hole transport property. This material is solved or dispersed in a solvent to be a hole transport ink which is printed by relief printing. In addition, it is desirable that volume resistivity of the formed hole transport layer should be 1×10⁶ Ω·cm or less in the light of light emitting efficiency.

In addition, for solvents dissolving a hole transport material, mixed solvents comprising solvents such as toluene, xylene, acetone, methyl ethyl ketone, methyl isobutyl ketone, cyclohexanone, methanol, ethanol, isopropanol, ethylene glycol, propylene glycol, polyethylene glycol, glycerine, ethyl acetate, butyl acetate, isopropyl acetate and water can be used. Accordingly, it is desirable that water or a solvent, wherein any amount of the solvent can be mixed with water, should be used.

In addition, a surface active agent, an antioxidant, a viscosity modifier or ultraviolet absorber may be added in a hole transport ink if necessary.

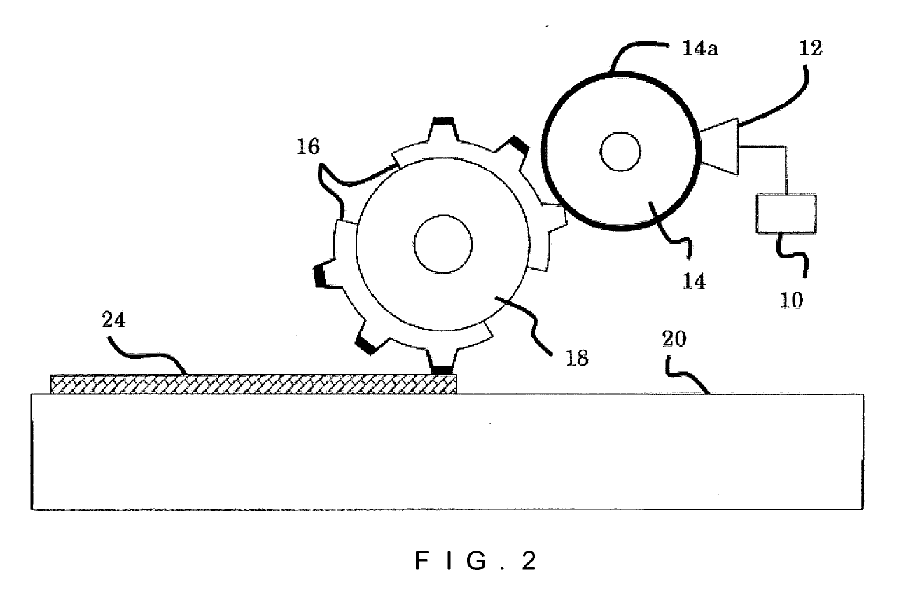

FIG. 2 is a schematic illustration of relief printing apparatus printing hole transport ink comprising hole transport material in the substrate including a pixel electrode and a partition wall. This printer has ink tank 10, ink chamber 12, anilox roll 14 and plate cylinder 18 on which relief printing plate 16 is put. A hole transport ink diluted with solvent is taken to ink tank 10. A hole transport ink is sent into ink chamber 12 from ink tank 10. Anilox roll 14 contacts with ink feed section of ink chamber 12, and it is supported rotatably.

And, according to rotation of an anilox roll 14, ink layer 14a comprising hole transport ink supplied on an anilox roll face becomes uniform. This ink layer transfers on relief parts (projection parts) of a plate 16 mounted on a printing cylinder 18 which is rotationally driven in proximity to an anilox roll. A substrate 24 on which transparent electrodes and an partition wall are formed is transported to a printing position of a flat base 20 by the transporting means that are not illustrated. And ink on relief parts of a plate 16 is printed on a substrate 24. And ink is dried if necessary. A hole transport layer is formed on a substrate in this way.

In addition, an embodiment of a relief printing plate is a water-developable light-sensitive resin relief printing plate.

For photosensitive resin plates, there are solvent developing type and water developing type. In the case of solvent developing type photosensitive resin plate, an organic solvent is used as a liquid developer of an exposed resin plate. In the case of water-developable photosensitive resin plate, water is used as a liquid developer for an exposed resin plate. A solvent developing type photosensitive resin plate shows resistance to water type ink. A water-developable photosensitive resin plate shows resistance to organic solvent system ink. In the present invention, all photosensitive resin plate having resistance to hole transport ink can be used.

According to the above-mentioned method, hole transport layer 4 is formed by printing a hole transport ink, by the above-mentioned relief printing method, on substrate 1 provided with partition wall 3, thereafter partition wall 3 and hole transport layer 4 are burned simultaneously. After the burning, the next process is conducted. The condition of the burning process where partition wall 3 and hole transport layer 4 are burned simultaneously is heating at 200° C.-250° C. for 10 minutes-60 minutes. At this burning process, both hole transport layer and partition wall are cured completely, thereby an organic electroluminescence device having enough resistant property can be obtained. In a case where the burning temperature is equal to or lower than 200° C., such temperature is too low for burning both a hole transport layer and a partition wall, thereby there may be such problems as non-hardening of a partition wall material and insufficient evaporation of water from a hole transport layer. On the other hand, in a case where the temperature is equal to 250° C. or higher, since such temperature is too high, there may be such problems as heat deterioration of a partition wall and a hole transport layer. In addition, in a case where the burning time is 10 minutes or shorter, the burning is insufficient. In a case where the burning time is 60 minutes or longer, productivity is bad.

After forming hole transport layer 4, an organic electroluminescence layer is formed. An organic light emitting layer is a layer emitting light by an electric current. For organic light emitting materials forming organic light emitting layers, the materials which a light emitting pigments such as coumarin system, perylene system, a pyran system, anthrone system, porphyrin system, quinacridon system, N,N′-dialkyl permutation quinacridon system, naphthalimido system, N,N′-diaryl permutation pyrrolo pyrrole series and iridium complex system are scattered in macromolecules such as polystyrene, polymethyl methacrylate and polyvinyl carbazole can be used.

In addition, high polymer materials such as poly arylene system, PAV [polyarylenevinylene] system, a poly fluorene system or a polyphenylene vinylene system can be used.

Organic light emitting ink is prepared by dissolving these organic light emitting materials in a solvent.

For a solvent dissolving an organic light emitting material, toluene, xylene, acetone, anisole, methyl ethyl ketone, methyl isobutyl ketone and cyclohexanone can be used. The above-mentioned solvent may be used alone. In addition, the above mentioned solvent may be used as mixed solvent.

Above all, aromatic organic solvent such as toluene, xylene and anisole is preferred from an aspect of solubility of an organic light emitting material.

In addition, a surface active agent, an antioxidant, a viscosity modifier, an ultraviolet absorber may be added to an organic light emitting ink if necessary.

In addition, for formation method of an organic light emitting layer pattern, relief printing can be used. In addition, ink jet process, intaglio offset printing and relief reversal offset printing can be used, too. In addition, when an organic light emitting layer is formed by relief printing, a plastic plate suitable to an organic light emitting ink can be used. Above all, a water-developable light-sensitive resin relief printing plate is preferred.

After having formed organic light emitting layer 5, a line pattern cathode layer 6 which is perpendicular to line pattern pixel electrodes is formed. For a material of a cathode layer 6, the material which is suitable for light emitting property of an organic light emitting layer can be used. For example, metal simple substance such as lithium, magnesium, calcium, ytterbium and aluminium can be used. An alloy of the above mentioned metal simple substance and the stable metal such as gold and silver can be used. In addition, conductive oxidate of indium, zinc, tin or the like can be used. For formation method of a cathode layer, a vacuum evaporation method using a mask (a sputter method, an ion plating method) can be used.

In addition, in the case of an organic electroluminescence element of the above mentioned embodiment, there are a hole transport layer and an organic light emitting layer between the pixel electrode which is an anode and a cathode layer. In addition, there may be a hole blocking layer, an electron transport layer, an electron injection layer between an anode and a cathode layer if necessary.

In addition, layer formation method shown in present specification can be used when the above mentioned layer is formed.

In addition, in this embodiment, a partition wall pattern is made to be hydrophilic and then a hole transport layer is formed while any organic electroluminescence medium layer such as an organic light emitting layer, a hole block layer, an electron transport layer and an electron injection layer can be formed.

Further, an entire supporting body supporting a partition wall part may be made to be hydrophilic. In a case where an entire supporting body is made to be hydrophilic, as for not only a partition wall part and an anode part but also a peripheral domain, a surface character becomes uniform, thereby an adhesive, an sealing agent or the like can be uniformly adhered to a peripheral domain

Finally an organic electroluminescent element is sealed using glass cap 7 and adhesive 8 to protect the organic electroluminescent element from outside oxygen and moisture. An organic electroluminescent display panel can be obtained in this way.

In addition, in the case of an organic electroluminescent element having a flexible transparent substrate, the organic electroluminescent element may be sealed using a sealing compound and a flexible film.

In a method of manufacturing an organic EL device comprising transferring an ink by relief printing to form a hole transport layer, by forming an even hole transport layer without ink repellent phenomenon, an organic EL device without a defect or an unevenness could be obtained.

Further, in a method of manufacturing an organic EL device comprising transferring an ink by relief printing to form an organic electroluminescence medium layer, by forming an even organic electroluminescence medium layer without ink repellent phenomenon, an organic EL device without a defect or an unevenness could be obtained.

### EXAMPLE

Examples of the present invention are described below.

### Example 1

ITO thin film was formed by sputter method on a glass substrate of which diagonal was 1.8 inches. Patterning of ITO thin film was performed by photolithography method and etching using an acid solution. Pixel electrodes were formed in this way.

Line pattern of pixel electrodes is described below. Line width was 136 μm. Space width was 30 μm. There were 192 lines on a glass substrate of 32 mm square.

Next, a partition wall was formed by following method:

Positive photosensitive polyimide (a product of TORAY INDUSTRIES, INC.: PHOTONEECE DL-1000) was applied to an entire surface of a glass substrate provided with a pixel electrode by spin coating. The condition of one spin coating comprised a rotation at 150 rpm for 5 seconds and a next rotation at 500 rpm for 20 seconds. Height of a partition wall was 1.5 μm. A photosensitive material formed on entire surface of a substrate was exposed and developed by photolithography method to form a line-pattern partition wall between pixel electrodes. After this process, a partition wall was irradiated by ultra-violet ray for 3 minutes using UV/03 cleaning apparatus (a product of ORK MANUFACTURING CO., LTD.) without burning of the partition wall.

Hole transport ink comprising the following material was made:

BAYTRON® AI-4083: 80 weight percent.

ultrapure water: 20 weight percent.

The viscosity of this PEDOT solution was 5.5 mPa·s. A hole transport layer was formed between partition walls by relief printing using the above mentioned ink.

After printing, both a partition wall and a hole transport layer were simultaneously burned in atmospheric air at 230 degrees Celsius for 30 minutes to form a partition wall and a hole transport layer. The hole transport layer thickness was 50 nm.

Patterning condition of the hole transport layer was checked.

A polyphenylene vinylene derivative (organic light emitting material) was dissolved in toluene. Density of a polyphenylene vinylene derivative was 1%. This was organic light emitting ink. This organic light emitting ink was used, and organic light emitting layer was formed by relief printing method on pixel electrodes between partition walls. The film thickness of organic light emitting layer after printing and drying was 80 nm.

Thereupon, a cathode layer comprising Al and Ca was formed. Mask evaporation method by resistance heating evaporation method was applied to the formation of a cathode layer. A pattern of a cathode layer was form of line. A line-shaped cathode layer is perpendicular to line pattern of anode electrodes. Glass cap and adhesive were used, and this organic electroluminescent assembly was sealed last to protect this organic electroluminescent assembly from external oxygen and moisture. In this way organic electroluminescent display panel was obtained. There are fetch electrode of an anode side and fetch electrode of a cathode side in a penumbra of display of an organic electroluminescent display panel. By connecting power supply to takeout electrodes, display of organic electroluminescent device was confirmed and checked.

### Example 2

An organic electroluminescent display panel was made by almost same method as example 1. However, BAYTRON® AI-4083 (80 weight percent) and ethanol (20 weight percent) were mixed and used for a hole transport ink.

### Example 3

An organic electroluminescent display panel was made by almost same method as example 1. However, BAYTRON® AI-4083 (60 weight percent), ethanol (20 weight percent) and isopropyl alcohol (20 weight percent) were mixed and used for a hole transport ink. After exposure and development of a partition wall, a partition wall was temporarily burned at 130° C. for 15 minutes.

### Example 4

An organic electroluminescent display panel was made by almost same method as example 1. However, after exposure and development of a partition wall, a partition wall was temporally hardened at 150° C. for 20 minutes.

### Reference Example 1

An organic electroluminescent display panel was made by almost same method as example 1. However, after exposing and developing of a partition wall, a partition wall was burned at 230° C. for 30 minutes. Then, after UV/03 cleaning was conducted, a hole transport layer was formed. BAYTRON® AI-4083 (80 weight percent) and ultrapure water (20 weight percent) were mixed and used for a hole transport ink.

### Reference Example 2

An organic electroluminescent display panel was made by almost same method as comparative example 1. However, BAYTRON® AI-4083 (60 weight percent), ethanol (20 weight percent) and isopropyl alcohol (20 weight percent) were mixed and used for a hole transport ink.

### Comparative Example 1

An organic electroluminescent display panel was made by almost same method as example 1. However, after exposure and development of a partition wall, UV/O₃ cleaning was not conducted.

### Comparative Example 2

An organic electroluminescent display panel was made by almost same method as example 4. However, after exposure and development of a partition wall, and temporally hardening at 150° C. for 20 minutes, UV/O₃ cleaning was not conducted.

Table 1 shows evaluation results of shapes of hole transport layer patterns and display results of manufactured organic EL displays of examples 1, 2, 3 and 4 and reference examples 1 and 2 and comparative examples 1 and 2.

Evaluation method was a visual check of a shape of a hole transport layer pattern. In addition, an obtained organic EL display was made to emit light, and unevenness was observed. In examples of the present invention, as for all EL displays, shapes of the patterns were good and the emitted lights were even. In comparative examples, ink-repellent phenomenon occurred and unevenness of the emitted light was observed.

In reference examples, ink-repellent phenomenon and whitening of a partition wall was observed a little while unevenness and defect in emitted light was not observed, therefore light emitting property was good.

TABLE 1

| | Shape of a hole transport | Emitted light |
|---|---|---|
| | layer pattern | (evenness) |
| Example 1 | ∘ | ∘ |
| Example 2 | ∘ | ∘ |
| Example 3 | ∘ | ∘ |
| Example 4 | ∘ | ∘ |
| Reference Example 1 | Δ | ∘ |
| | (Ink was repelled a little.) | |
| Reference Example 2 | Δ | ∘ |
| | (A partition wall was | |
| | whitened a little.) | |
| Comparative Example 1 | x | x |
| | (Ink was repelled.) | |
| Comparative Example 2 | x | x |
| | (Ink was repelled.) | |

What is claimed is:

1. A method of manufacturing an organic electroluminescence device, comprising:
making a partition wall pattern hydrophilic; and
forming an organic electroluminescence medium layer by transferring an ink in an area sectioned by the partition wall by relief printing.

2. The method of manufacturing an organic electroluminescence device according to claim 1,
wherein the method includes
applying a photosensitive resin composition on a substrate; and
forming the partition wall pattern by exposing a pattern of the resin and developing the resin.

3. The method of manufacturing an organic electroluminescence device according to claim 1,
wherein making the partition wall pattern hydrophilic is irradiating light.

4. The method of manufacturing an organic electroluminescence device according to claim 1,
wherein making the partition wall pattern hydrophilic is conducting a plasma exposure.

5. The method of manufacturing an organic electroluminescence device according to claim 1,
wherein making the partition wall pattern hydrophilic is conducting a corona discharge.

6. The method of manufacturing an organic electroluminescence device according to claim 1,
wherein making the partition wall pattern hydrophilic and making the area sectioned by the partition wall pattern hydrophilic are simultaneously conducted.

7. The method of manufacturing an organic electroluminescence device according to claim 1,
wherein making the partition wall pattern hydrophilic and making a supporting body supporting the partition wall pattern hydrophilic are simultaneously conducted.

8. The method of manufacturing an organic electroluminescence device according to claim 1,
wherein the organic electroluminescence medium layer is a hole transport layer.

9. The method of manufacturing an organic electroluminescence device according to claim 2,
wherein the method include hardening the partition wall pattern by heat processing at a temperature of 160° C. or lower.

10. The method of manufacturing an organic electroluminescence device according to claim 8,
wherein the partition wall and the hole transport layer are simultaneously burned at 200-250° C. for 10-60 minutes after forming the hole transport layer.

11. The method of manufacturing an organic electroluminescence device according to claim 8,
wherein a forming material of the hole transport layer is a water type dispersion liquid having pH of 3 or lower.

12. The method of manufacturing an organic electroluminescence device according to claim 8,
wherein a forming material of the hole transport layer comprises PEDOT:PSS.
